(19) United States
(12) Patent Application Publication
(10) Pub. No.: US 2018/0076373 A1
(43) Pub. Date: Mar. 15, 2018

(54) SOLUTION PHASE SYNTHESIS OF HIGHLY PROCESSIBLE NANOCRYSTALLINE LiZnP AND SIMILAR TERNARY SEMICONDUCTORS

(71) Applicants: Javier Vela-Becerra, Ames, IA (US); Miles Arthur Burris White, Clinton, IA (US); Michelle JoAnn Thompson, Huxley, IA (US); Gordon J. Miller, Ames, IA (US)

(72) Inventors: Javier Vela-Becerra, Ames, IA (US); Miles Arthur Burris White, Clinton, IA (US); Michelle JoAnn Thompson, Huxley, IA (US); Gordon J. Miller, Ames, IA (US)

(73) Assignee: Iowa State University Research Foundation, Inc., Ames, IA (US)

(21) Appl. No.: 15/702,570

(22) Filed: Sep. 12, 2017

Related U.S. Application Data
(60) Provisional application No. 62/394,068, filed on Sep. 13, 2016.

(51) Int. Cl. H01L 35/26; C01B 25/08; C22C 12/00; H01L 31/18; H01L 31/0384; H01L 35/34

(52) U.S. Cl. CPC H01L 35/26; C01B 25/088; C22C 12/00; H01L 31/18; H01M 10/0525; H01L 35/34; C01P 2006/32; C01P 2006/40; H01L 31/03845

(57) ABSTRACT

Nowotny-Juza phases offer a wide range of potential applications including solar cell and thermoelectric device fabrication. The disclosure presents a solution phase synthesis of the Nowotny-Juza semiconductors LiZnP, LiCdP, and LiZnSb. These samples are phase pure, crystalline, and exhibit particle sizes of around 20 nm.

### CROSS-REFERENCE TO RELATED PATENT APPLICATIONS

This patent application claims the benefit of U.S. Provisional Patent Application No. 62/394,068, filed Sep. 13, 2016, the entire teachings and disclosure of which are incorporated herein by reference thereto.

### STATEMENT REGARDING FEDERALLY SPONSORED RESEARCH AND DEVELOPMENT

This invention was made in part with Government support under Grant Number CHE1253058 awarded by the National Science Foundation. The Government has certain rights in this invention.

### FIELD OF THE INVENTION

This invention generally relates to half-Heusler phase materials, and in particular, this invention relates to Nowotny-Juza phase materials and methods of producing same that are usable in a variety of electronic applications.

### BACKGROUND OF THE INVENTION

Nowotny-Juza phase materials are intermetallic crystal materials with potential for a variety of applications. A subset of the half-Heusler compounds (i.e., ternary compounds of the general formula XYZ, where X is an element from group I or XI, Y is an element from group II or XII, and Z is an element from group V), Nowotny-Juza phases are of interest because their electronic structure makes them amenable to applications in solar cells (light-to-energy conversion), thermoelectrics (heat-to-energy conversion), optoelectronics (LEDs, laser diodes), and anode materials for batteries.

In particular, thermoelectric materials offer an attractive means of generating electricity from heat that would otherwise be wasted. However, thermoelectrics have failed to reach large scale commercialization due to their relatively high cost and low device efficiency. The challenge with enhancing thermoelectric performance (given by the figure of merit, zT) arises from having to optimize three concordant properties (Seebeck coefficient S, electrical conductivity σ, and thermal conductivity κ), all of which are dependent on carrier concentration. This problem makes it difficult to intuitively increase the zT figure of merit in thermoelectric materials.

LiZnP may be a promising material for a variety of these applications, but the difficulty in preparation has hampered development of applications using it. For example, Kuriyama et al. (“Crystal growth and characterization of the filled tetrahedral semiconductor LiZnP,” Journal of Crystal Growth 108 (1991) 37-40) describe a conventional method of preparing LiZnP via directional solidification over the course of over 120 hours. U.S. Pat. No. 8,414,746 (Geoffrey F. Strouse et al., “Nanoparticle Synthesis and Associated Methods,” issued Apr. 9, 2013) describes a method for synthesizing LiZnP by superheating reagents using microwave radiation; however, the actual synthesis conditions for producing LiZnP were not described. Kuriyama et al. and U.S. Pat. No. 8,414,746 are both incorporated in their entireties herein by reference.

### BRIEF SUMMARY OF THE INVENTION

Embodiments of the present invention provide a straightforward and relatively quick method of synthesizing pure LiZnP, LiCdP and LiZnSb crystals using solution phase chemistry. These and other advantages of the invention, as well as additional inventive features, will be apparent from the description of the embodiments of the invention provided herein.

In one aspect, embodiments of the present invention provide a method of producing Nowotny-Juza phases through solution chemistry. Group I, II, and V reagents were combined at elevated temperatures, and nanoscale particles of Nowotny-Juza phase-pure materials were allowed to grow over time.

In a specific aspect, embodiments of the present invention provide a method of synthesizing LiZnP particles. The method includes the steps of combining a zinc-containing compound, such as diethyl zinc, zinc chloride, zinc stearate, etc., and a lithium-containing compound, such as phenyl lithium, lithium hydride, lithium di-isopropyl amide, n-butyl lithium, etc., with a phosphorus-containing compound, such as tri-n-octylphosphine, triphenylphosphine, etc., and heating the mixture to an elevated temperature, which in one embodiment is to a temperature of 330° C.

In another specific aspect, the invention provides a method of synthesizing LiCdP particles. The method includes the steps of combining a cadmium-containing compound, such as dimethyl cadmium, cadmium chloride, etc., and a lithium-containing compound, such as phenyl lithium, lithium hydride, lithium di-isopropyl amide, n-butyl lithium, etc., with a phosphorus-containing compound, such as tri-n-octylphosphine, triphenylphosphine, etc., and heating the mixture to an elevated temperature, which in one embodiment is to a temperature of 330° C.

In still another specific aspect, the invention provides a method of synthesizing LiZnSb particles. The method includes the steps of combining a zinc-containing compound, such as diethyl zinc, zinc chloride, zinc stearate, etc., and a lithium-containing compound, such as phenyl lithium, lithium hydride, lithium di-isopropyl amide, n-butyl lithium, etc., with a antimony-containing compound, such as triphenylantimony, etc., dissolved in an organic solvent and heating the mixture to an elevated temperature, which in one embodiment is to a temperature of 300° C. Notably, the LiZnSb has a cubic crystal structure, instead of a hexagonal crystal structure, making it the first reported Nowotny-Juza phase to exhibit polytypism.

Other aspects, objectives and advantages of the invention will become more apparent from the following detailed description when taken in conjunction with the accompanying drawings.

### BRIEF DESCRIPTION OF THE DRAWINGS

The accompanying drawings incorporated in and forming a part of the specification illustrate several aspects of the present invention and, together with the description, serve to explain the principles of the invention. The following paragraphs contain a brief summary of each figure or set of figures contained in the drawings.

FIG. 1A is a partial unit cell of LiZnP without Li atoms showing the covalent zinc-blende lattice of Zn and P. FIG. 1A shows one representation of the zinc-blende lattice of Zn and P. The positions of the Zn and P can change due to coloring. Additionally, FIG. 1A also is representative of the partial unit cell for LiCdP and LiZnSb.

FIG. 1B is a unit cell of LiZnP with Li occupying octahedral holes in the (ZnP)⁻ lattice. As with FIG. 1A, the unit cell depicted in FIG. 1B is also representative of the unit cells for LiCdP and LiZnSb.

FIG. 2 is a powder XRD of LiZnP with varying time spent at 330° C. and with standard patterns of potentially present phases provided at the bottom of the plot.

FIG. 3A is a graph representing change in particle size of LiZnP as a function of time spent refluxing at 330° C.

FIG. 3B is a graph representing change in composition of LiZnP as a function of time spent refluxing at 330° C.

FIG. 4A is a representative TEM image of LiZnP aggregates.

FIG. 4B is a SAED of LiZnP with the visible reflections labelled with their corresponding lattice plane.

FIG. 5A is a UV-Vis absorbance spectrum for LiZnP.

FIG. 5B is a Tauc plot displaying the direct forbidden band gap of LiZnP.

FIG. 6 depicts powder XRD of LiCdP with varying time spent at 330° C. and with standard patterns of potentially present phases provided at the bottom of the plot.

FIG. 7 depicts powder X-ray diffraction pattern for cubic LiZnSb. The standard patterns provided are the previously observed hexagonal pattern (unobserved), antimony metal (33% impurity), and the calculated cubic reference pattern (67% majority).

FIGS. 8A-8D depict unit cells, local environments, and energy vs. volume curves for the hexagonal and cubic LiZnSb polytypes. FIG. 8A depicts the unique crystallographic sites that impact total energy are labelled as the “coloring site.” FIG. 8B depicts energy vs. volume curves for each of the constituent elements occupying the coloring site for the hexagonal phases. FIG. 8C depicts a comparison between the lowest energy coloring patterns for hexagonal and cubic phases is given as a difference relative to the energy of the optimized cubic geometry. FIG. 8D depicts energy vs. volume curves for each of the constituent elements occupying the coloring site for the cubic phases.

FIGS. 9A-9D depict thermoelectric properties at 600K of cubic LiZnSb calculated using TB-mBJ with both Zn (solid) and Sb (dashed) occupying the 4c site. Seebeck coefficient (FIG. 9A) and thermopower (FIG. 9B) versus Fermi level have the Fermi level placed directly in the middle of the band gap. Thermal conductivity (FIG. 9C) and zT (FIG. 9D) versus doping are given so that −ve and +ve doping levels correspond to n- and p-type, respectively.

FIGS. 10A-10B depict band structure and density of states of cubic LiZnSb calculated using TB-mBJ with Zn (FIG. 10A) and Sb (FIG. 10B) filling the 4c site. The site occupancy most notably changes the nature of the band gap from indirect to direct between Zn and Sb, respectively. The maximum valence band also becomes much broader with Zn occupancy.

FIGS. 11A-11B depict the band structure and density of states of cubic LiZnSb calculated using PBE-GGA with Zn (FIG. 11A) and Sb (FIG. 11B) filling the 4c site. The change in the nature of band gap is the same as with TB-mBJ as is the nature of the maximum valence band.

FIG. 12 depicts experimental vs. calculated lattice constant for cubic Nowotny-Juza phases. The dashed center line corresponds to a perfect match between experiment and computation, and the outer dashed lines indicate an under/overestimation of 2%. Previously reported phases are indicated with white markers and cubic LiZnSb is shown in black.

FIGS. 13A-13D depict thermoelectric properties at 600K of cubic LiZnSb calculated using GGA-PBE with both Zn (solid) and Sb (dashed) occupying the 4c site. Seebeck coefficient (FIG. 13A) and thermopower (FIG. 13B) versus Fermi level have the Fermi level placed directly in the middle of the band gap. Thermal conductivity (FIG. 13C) and zT (FIG. 13D) versus doping are given so that −ve and +ve doping levels correspond to n- and p-type, respectively.

FIGS. 14A-14B depict the figure of merit vs. carrier concentration as a function of temperature for TB-mBJ (FIG. 14A) and PBE (FIG. 14B).

While the invention will be described in connection with certain preferred embodiments, there is no intent to limit it to those embodiments. On the contrary, the intent is to cover all alternatives, modifications and equivalents as included within the spirit and scope of the invention as defined by the appended claims.

### DETAILED DESCRIPTION OF THE INVENTION

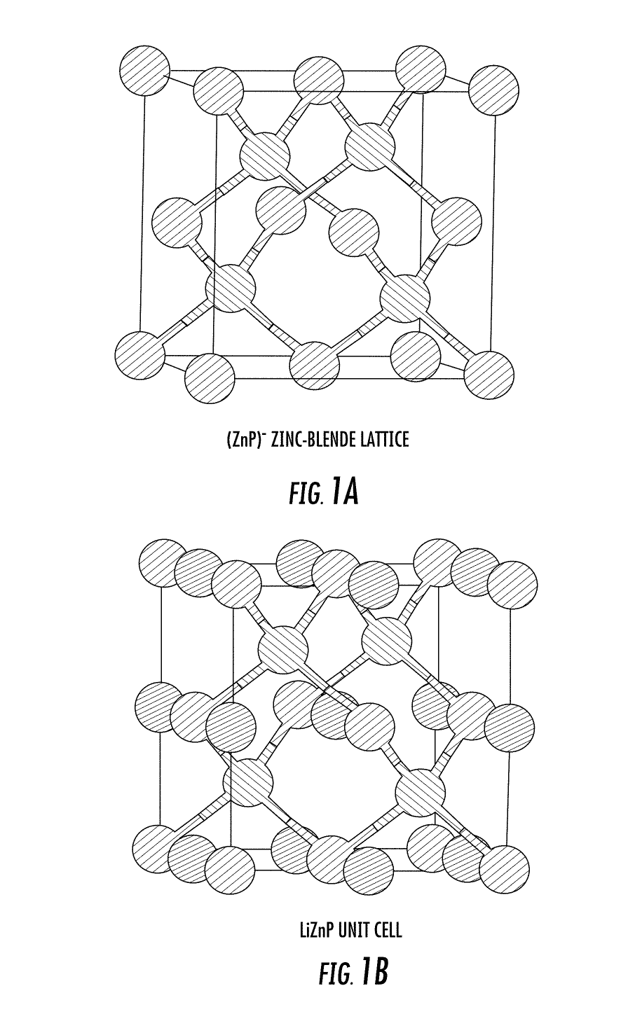

Half-Heusler phases are a class of compounds described by the general formula XYZ. The structure of these phases can be described as a zinc-blende lattice of Y and Z (FIG. 1A) stuffed with an interpenetrating fcc lattice of X (FIG. 1B). A special instance of these compounds is when X, Y, and Z are made of elements from group I/XI, II/XII, and V, respectively (for instance Li, Zn, and P). These compounds, known as Nowotny-Juza phases, have unique electronic structures and potential application in optoelectronics, solar cells, thermoelectrics, neutron detectors, and anode materials in lithium-ion batteries. Their electronic structure resembles that of classical group IV or III-V 8e-semiconductors, presumably due to the presence of the (II-V)-zinc blende lattice. Experimental and computational observations confirm the semiconducting nature of these materials, suggesting their utility in solar and thermoelectric device applications.

The 18e- half-Heusler phases have already shown promise for thermoelectric application with zT values of over 1.0. A recent computational investigation of Nowotny-Juza phases showed their high power conversion efficiencies and large carrier effective masses, both of which are promising signs for their ability to be implemented into thermoelectric devices. In terms of solar devices, Nowotny-Juza phases may be used as a buffer layer in CuInₓGa(₁₋ₓ)Se₂ (CIGS) solar cells. A buffer layer of this type should contain a material with a band gap of no less than 2.0 eV and a lattice constant of 5.9 Å. Currently, CdS and other cadmium containing compounds are used to satisfy these criteria. However, an alternative material is desirable due to the toxicity of cadmium. LiZnP has a band gap and lattice constant matching those of desirable materials. Additionally, the similar unit cell enables very little lattice mismatch between LiZnP and the CIGS absorbing layer.

Despite the potential use of LiZnP and other Nowotny-Juza phases, their synthesis has been limited to the bulk through the use of high temperature solid-state reactions from the constituent elements. Low temperature and solution phase preparation are more convenient and are desirable to fully investigate the potential usefulness of these materials. As disclosed herein, LiZnP and LiCdP are synthesized using solution chemistry, and both LiZnP and LiCdP, made according to the disclosed method, exhibit nanoscale particle size.

In an embodiment, nanocrystalline LiZnP was synthesized by combining a zinc-containing compound, such as diethyl zinc, zinc chloride, zinc stearate, etc., and a lithium-containing compound, such as phenyl lithium, lithium hydride, lithium di-isopropyl amide, n-butyl lithium, etc., with a phosphorus-containing compound, such as tri-n-octylphosphine, triphenylphosphine, etc., and heating the mixture to an elevated temperature, which in one embodiment is to a temperature of 330° C. In a particular embodiment, nanocrystalline LiZnP was synthesized from tri-n-octylphosphine (TOP), lithium hydride, and diethyl zinc (injected at 250° C.) at 330° C. using the reaction shown in Equation 1, below.

$$LiH + {Et}_{2} Zn + TOP \begin{matrix}1 ) 250 ° C . ( injection ) \\ \\ 2 ) 300 ° C . time\end{matrix} LiZnP \qquad ( Equation 1 )$$

In an exemplary embodiment, synthesis of LiZnP took place using the following reagents and processing conditions. 5 mL Tri-n-octylphosphine (“TOP” 97%; Strem Chemicals, Inc.) and 10-20 mg of lithium hydride (powder, 97%; Alfa-Aesar, Thermo Fisher Scientific) were added to a three-neck flask in a nitrogen filled glove box. The flask was then degassed for 30 minutes followed by refilling with Ar and heating to 250° C. Diethyl zinc (56 wt. % Zn; Sigma Aldrich), in the case of LiZnP, or dimethyl cadmium (97%; Strem Chemicals, Inc.), for the synthesis of LiCdP (discussed in more detail below), was then immediately injected. The reaction mixture was then heated to 330° C. over the course of 10 minutes followed by continuous stirring over 10, 20, 45, and 90 minutes. The crude product was washed with 10 mL of toluene followed by centrifugation at 5000 rpm for 10 minutes. The washed product was then once again washed with enough toluene to re-suspend the particles (roughly 3 mL). This washing cycle was performed to remove excess ligand and solvent present within the crude solution.

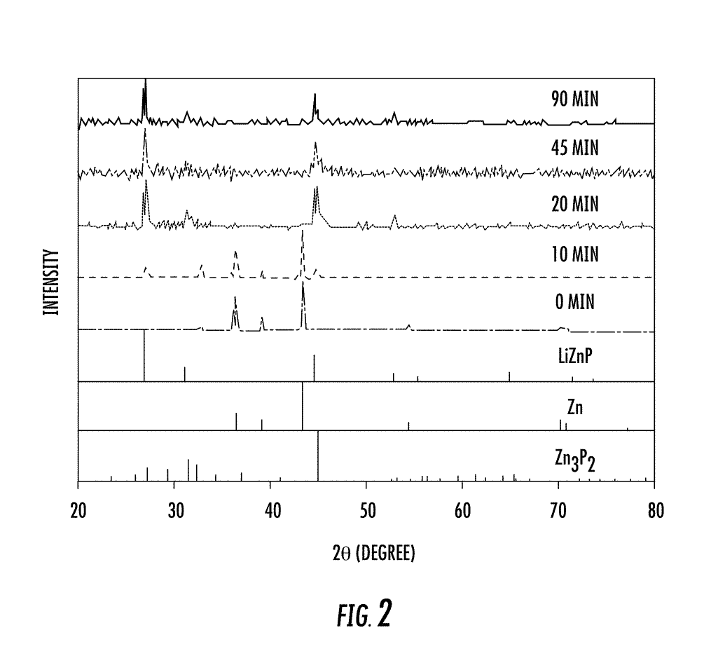

TOP was chosen as a P source due to its ability to act as a surface ligand while simultaneously being effective in other metal phosphide nanoparticle preparations. The effect of time on the reaction was monitored using powder X-ray diffraction (XRD) as shown in FIG. 2. Powder X-ray diffraction data were measured using Cu Ka radiation on a Rigaku Ultima IV diffractometer. The data clearly show that metallic zinc forms almost immediately upon injection of diethyl zinc into the reaction solution. This behavior is reminiscent of that reported during the colloidal synthesis of Zn₃P₂ quantum dots. When Zn₃P₂ was synthesized using a similar reaction temperature (350° C.) and TOP as the phosphorus source, metallic zinc species were observed prior to zinc phosphide formation. The formation of LiZnP seems to progress through a similar mechanism, with phosphorus being reduced from a “formal” oxidation state of 3+ in TOP to 3− in LiZnP.

The formation of LiZnP occurs at a greatly accelerated pace (or in much shorter reaction time) compared to other metal phosphide nanoparticles, most likely due to the reductive environment caused by the excess LiH precursor in solution. LiZnP begins to appear within 10 min at 330° C. and becomes the only observable crystalline phase within 20 min. Longer reaction times beyond 20 min lead to narrowing of the diffraction peaks observed by powder XRD. This is indicative of the formation of larger particle sizes. The approximate change in phase and particle size (estimated by the Scherrer equation) as a function of reaction time is shown in FIGS. 3A and 3B. LiZnP does not appear to decompose even after extended times at 330° C. This characteristic is expected due to the high thermal stability of half-Heusler phases (Table 1, below).

TABLE 1
Synopsis of data related to synthesis of LiZnP. Reaction conditions
are constant while the time spent at 330° C. impacts the evolution
of the phase as well as particle size.

| | | Time at | | Particle |
|---|---|---|---|---|
| Compound | Conditions* | 330° C. | Composition | Size |
| LiZnP | 20 μL Et₂Zn | 0 min | 0% LiZnP | Not Present |
| | injection into 20 gm | 10 min | 20% LiZnP | 15.7 nm |
| | LiH in 5 mL | 20 min | 100% LiZnP | 20.4 nm |
| | TOP | 45 min | 100% LiZnP | 23.3 nm |
| | | 90 min | 100% LiZnP | 28.2 nm |

*Injection occurred at 250° C. followed by a ramp time of 10 minutes up to the growth temperature of 330° C.

Using a transmission electron microscope (TEM), energy-dispersive X-ray spectroscopy (EDX) measurements were used to further characterize the LiZnP particles. Transmission electron microscopy was conducted on carbon-coated nickel grids using a FEI Technai G2F20 field emission scanning transmission electron microscope (STEM) at 200 kV (point-to-point resolution<0.25 nm, line-to-line resolution<0.10 nm). ICP-MS (inductively coupled plasma mass spectrometry) data was collected on a sample of LiZnP and the elemental composition was found to be 31.7±0.2%, 40±2%, and 28.8±0.8% for Li, P, and Zn, respectively. This corresponds to a 1.1:1.0:1.4 elemental ratio in Li:Zn:P. The excess phosphorus can be attributed to the surface passivating tri-n-octylphosphine ligands.

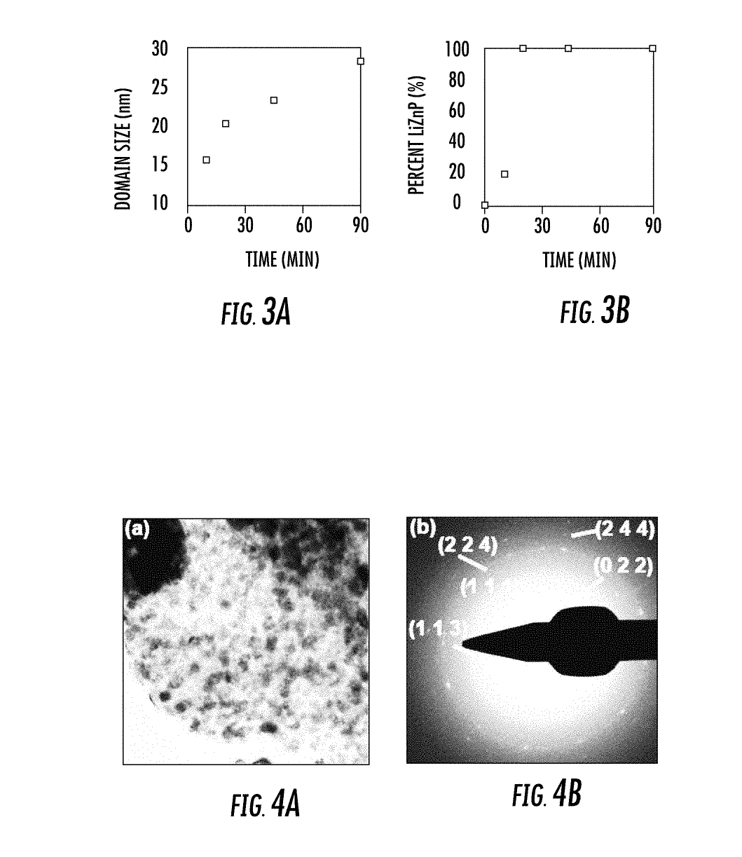

Also using TEM, select area electron diffraction (SAED) helped in identifying the crystalline phases present within the samples. Distinct powder rings without outlier reflections show the high level of crystallinity processed by these particles as well as the absence of other identifiable crystalline phases (FIGS. 4A and 4B). The observed reflections correspond well to the lattice d-spacings expected for LiZnP. The reflection that is anticipated to be most intense (111) is located very close to the beam stop and is difficult to discern. Instead, the first easily observed ring is the place expected to be the second most intense (022). As such, this ring is the most prominent in the SAED. The other observed reflections all agree with d-spacings for planes within LiZnP. This supports the observed powder patterns, which show little to no impurity phases.

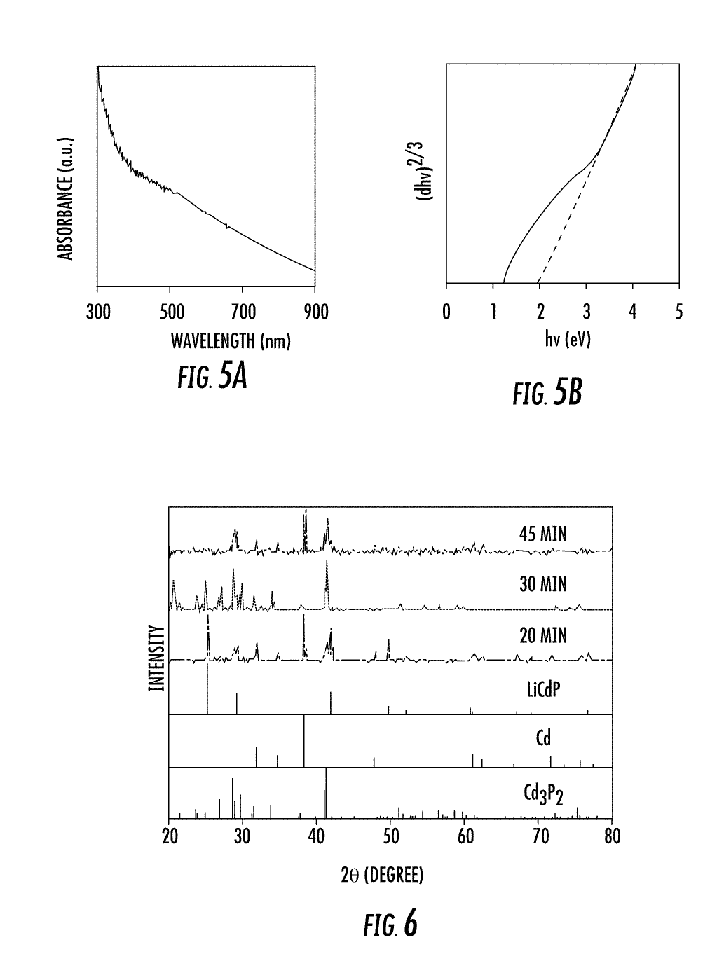

The electronic and optical properties of LiZnP nanoparticles are important, at least in part, for their potential integration into solar cells. FIG. 5A depicts the UV-Vis absorbance spectrum for LiZnP. Absorption spectra were measured with a photodiode array Agilent 8453 UV-Vis-NIR spectrophotometer. The optical absorption spectrum of LiZnP show the presence of a direct forbidden band gap. The magnitude of this gap was found to be 2.0 eV using a Tauc plot (FIG. 5B). This agrees well with the reported band gap for bulk LiZnP and prior electronic structure calculations. The lack of sharp absorption features suggests the LiZnP particles are not quantum confined. This observation makes sense due to the large carrier effective masses present within Nowotny-Juza phases. While the large effective masses do not allow for size-dependent quantum confinement and band gap tuning, they can be ideal and optimal for the development of more efficient thermoelectric materials.

Based on the ability to synthesize LiZnP nanocrystals, it was surmised that other Nowotny-Juza phases could possibly be synthesized through the same approach. Thus, dimethyl cadmium was substituted for diethyl zinc and attempts were made to synthesize LiCdP. Powder XRD patterns obtained after different reaction times (FIG. 6) reveal the formation of LiCdP, accompanied by some identifiable impurity phases. Contrary to LiZnP, further heating of LiCdP leads to its decomposition. While the initial mechanism of formation appears in line with LiZnP due to the formation of Cd metal and a small amount of LiCdP, longer heating times promote the formation of Cd₃P₂ instead. The inability to generate completely phase pure LiCdP through the simple procedure of replacing the dialkyl precursor is not entirely surprising or unprecedented. For instance, while Zn₃P₂ requires the use of highly reactive zinc species for its various synthesizes, Cd₃P₂ has a tendency to form under much milder precursors.

Besides LiZnP and LiCdP, LiZnSb was synthesized using solution phase techniques. As with LiZnP and LiCdP, using solution phase techniques to produce LiZnSb provides certain advantages. For example, hot-injection generally results in reduced particle size, which has been shown to lower thermal conductivity and, with it, increase thermoelectric efficiency. Further, precursor manipulation can provide better synthetic control compared to traditional solid-state synthesis.

Lightly doped, n-type (0.01 e-/u.c.) LiZnSb has been calculated to have a zT˜2 at 600 K However, the syntheses of n-type LiZnSb attempted to date has resulted in unintentionally doped, p-type LiZnSb with a zT<0.1. Using embodiments of the solution phase technique disclosed herein, lightly doped (<0.02 carriers/u.c.) n-type and p-type forms of LiZnSb are calculated to exhibit exceptional zT values of 1.64 and 1.43, respectively, at 600 K.

In one embodiment, the following materials and steps were used to form LiZnSb through solution phase synthesis. Triphenylantimony (Ph₃Sb, 700-750 mg, 2.0 mmol, 97%, Strem) and 1-octadecene (5 mL, 90%/technical grade, Sigma Aldrich) were added to a three-neck flask. The flask was then degassed for 30 minutes followed by refilling with Ar and heating to 250° C. N-butyllithium (0.125 mL, 0.2 mmol, 1.6 M in hexane, Sigma Aldrich) and diethyl zinc (0.02 mL, 0.2 mmol, 56 wt. % Zn, Sigma Aldrich) were then immediately injected in quick succession. The reaction mixture was heated to 300° C. over the course of 10 minutes followed by continuous stirring over a 4 hour period. The crude product was washed twice with toluene (3-10 mL) and ethanol (5 mL) followed by centrifugation at 5000 rpm for 10 minutes.

LiZnSb synthesized using the solution phase method discussed above exhibits a previously unknown cubic structure (a=6.23 Å from Rietveld refinement). Reportedly, bulk LiZnSb made by solid-state synthesis exhibited a hexagonal structure. Thus, LiZnSb made using the solution phase method is the first example of polytypism within the Nowotny-Juza phases. As discussed above, these phases are usually described as comprised of a wurtzite or zinc-blende sublattice of group II and V elements stuffed with a monovalent closed shell group I cation. Because this tetrahedral sublattice is isostructural and isoelectronic with classic 8 electron semiconductors, a low energy barrier for rearrangement of the structural component is possible.

To probe the energy difference between the hexagonal and cubic polytypes, the Vienna ab initio simulation package (VASP) was used. All VASP calculations used projected augmented-wave (PAW) pseudopotentials with a cutoff energy of 500 eV and a convergence energy of 1×10⁻⁶ eV. A conjugated algorithm was applied to the structural optimization with an 11×11×11 Monkhorst-pack k-points grid. During structural optimization, atomic coordinates as well as cell volume were allowed to relax except for energy vs. volume curves, where the cell volume was fixed. For hexagonal volumes, a c/a ratio was established based on a geometry optimization and then used for energy vs. volume curves. In the cubic case, this step was not required due to the symmetric lattice parameters. Total energy was calculated using the tetrahedron method with Blöchl corrections applied. VASP calculations treated exchange and correlation by the local density approximation (LDA) and the Perdew-Burke-Ernzerhof (PBE) generalized gradient functional in the case of total energy calculations. To estimate accurate gaps from the band structures, the Tran-Blaha modified Becke-Johnson (TB-mBJ) potential was utilized. Transport properties were calculated using the rigid-band approximation and constant scattering time approximation as implemented by the BoltzTraP code. For these calculations, a much denser 41×41×41 k-point grid was used with the TB-mBJ potential due to the importance of an accurate band gap for transport property calculations. Denser k-meshes were used but found to yield similar results.

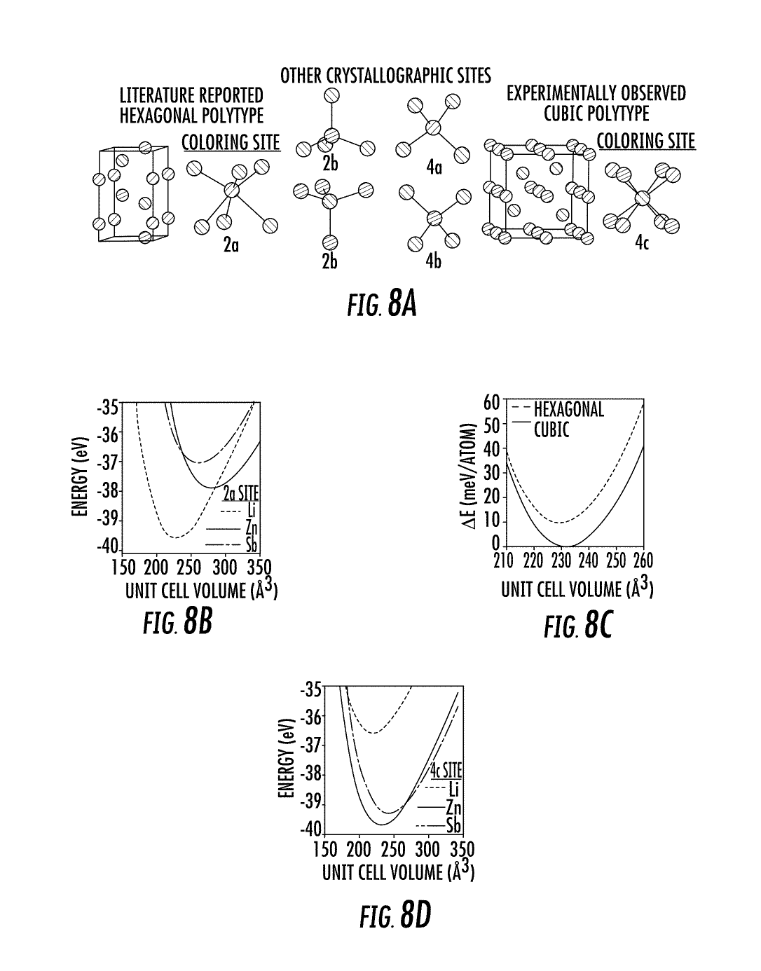

The experimentally reported hexagonal crystal structure of LiZnSb is comprised of a (ZnSb)⁻ wurtzite lattice stuffed with lithium. The analogous cubic polytype would be comprised of a (ZnSb)⁻ zinc blende lattice stuffed with lithium. However, unlike the hexagonal case, where the two wurtzite lattice positions are crystallographically equivalent, those positions in the zinc blende lattice are inequivalent (FIG. 8A). Site 4c has a coordination environment that is a heterocube formed by a tetrahedral coordination to the other two constituent elements. Site 4b has tetrahedral coordination to the 4c site and octahedral coordination to the 4a site. Because of this, the choice of coloring pattern, i.e. the distribution of elements across possible crystallographic sites, greatly impacts total energy calculations. To examine each of these different coloring patterns, without breaking the crystal symmetry, total energy vs. volume curves were plotted for cubic and hexagonal polytypes (FIGS. 8B and 8D).

The lowest energy coloring pattern for the hexagonal polytype agrees with experimental observations from prior solid state synthesis of bulk LiZnSb. Having either Zn or Sb stuffing (occupying) the 2a site in a lithium based wurtzite lattice is found to be much higher in energy (FIG. 8B). Similarly, in the cubic case, having lithium occupy the 4c site and being involved in the covalent zinc blende network is not preferred (FIG. 8D). Also as shown in FIG. 8D, while not as unfavorable as Li, Sb occupying the 4c site is also energetically unfavorable. This is contrary to other cubic Nowotny-Juza phases, LiZnPn (Pn =N, P, As), known in the bulk, which show a preference for the pnictide occupying the heterocubic site. In fact, cubic LiZnSb is the first instance of a Nowotny-Juza phase with the group II element occupying the 4c site (see Table 2, below).

To ensure the validity of this coloring approach, energy vs. volume curves were generated for a larger, comprehensive family of pnictide-containing cubic Nowotny-Juza phases as shown in Table 2. In all cases where a bulk experimental crystal structure is known, this matches the lowest calculated energy coloring pattern. The transition in cubic site preference occurs upon moving to the heavier pnictides (Sb and Bi). However, only the hexagonal phases of both LiZnSb and LiZnBi have previously been reported.

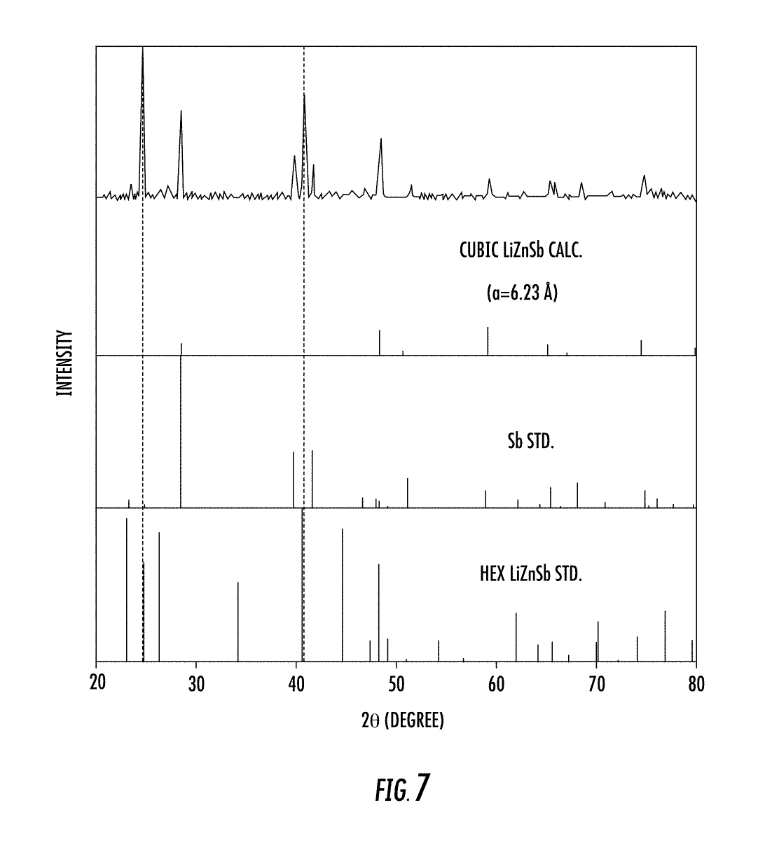

Along with a considerable energy difference, a noticeable change in lattice parameter is expected between coloring patterns. The experimental lattice parameter aₑₓₚ obtained after Rietveld refinement for the samples is 6.23 Å (see FIG. 7), slightly larger than the lattice constant of 6.14 Å calculated using the local density approximation (LDA). This method underestimates the known experimental lattice parameters of all reported cubic Nowotny-Juza phases by an average of 1.41% as shown in Table 2, but LDA accurately predicts the experimentally observed coloring pattern. Additionally, LDA underestimates the lattice parameters of the hexagonal LiZnSb polytype by 2.03% (aₑₓₚ vs. a_{calc}; see Table 3, below). These results render the slightly low estimate (by 1.44%) for Zn occupying the 4c site consistent with the limitations of this method, and are in line with similar low estimates obtained by LDA in other classes of compounds.

TABLE 3
Coloring preference and calculated lattice constant for hexagonal LiZnSb.

| | 2a site | ΔE | aₑₓₚ | a_{calc} | c/aₑₓₚ | c/a_{calc} |
|---|---|---|---|---|---|---|
| Phase | occupancy | (meV/atom) | (Å) | (Å) | (Å) | (Å) |
| LiZnSb | Li | 0 | 4.43 | 4.34 | 1.62 | 1.62 |
| | Zn | 213.5 | | 4.30 | | 1.90 |
| | Sb | 142.2 | | 4.39 | | 1.91 |

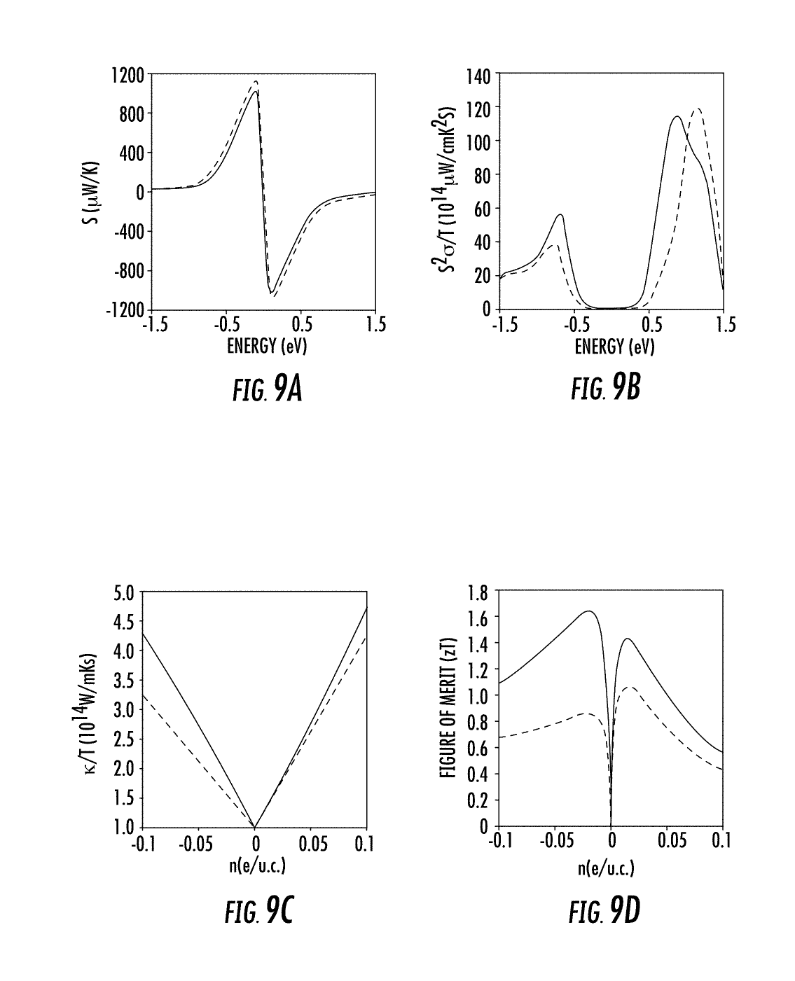

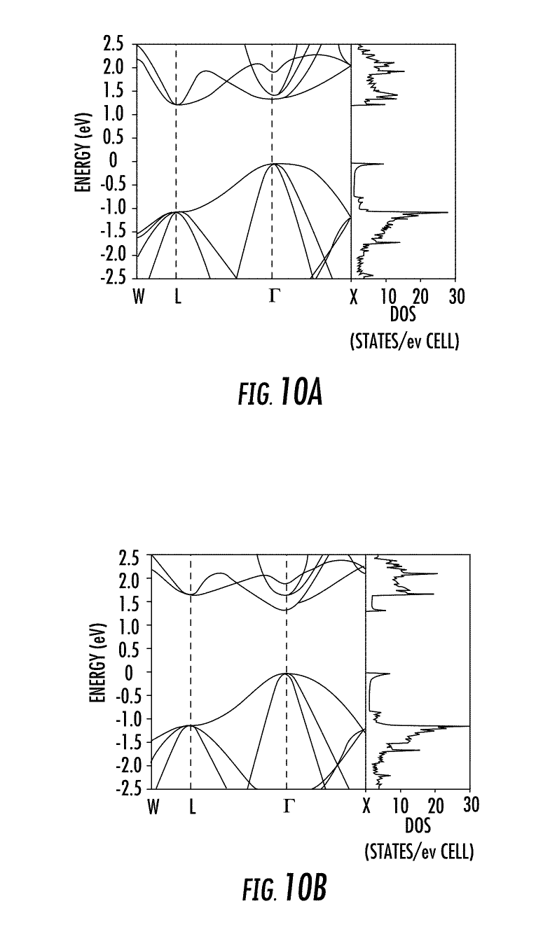

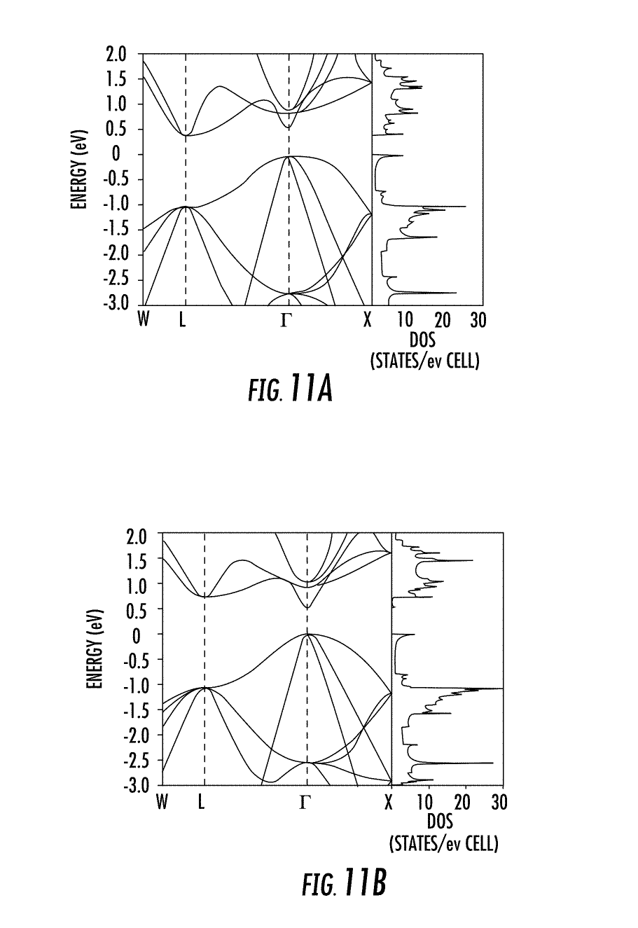

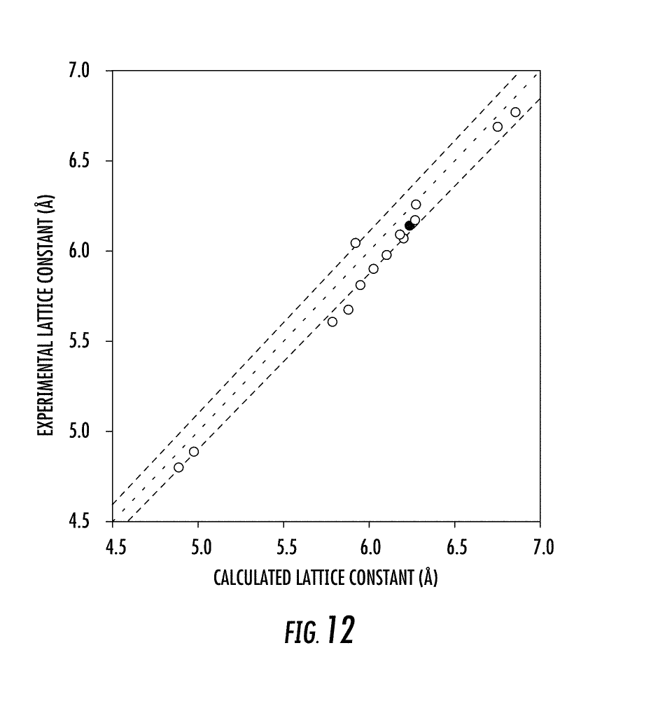

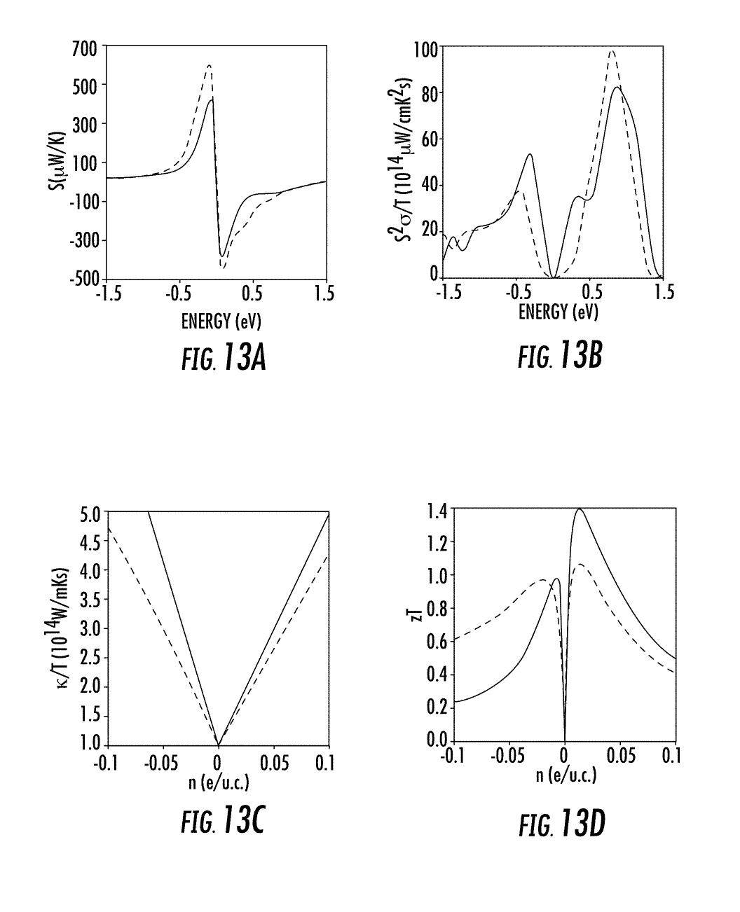

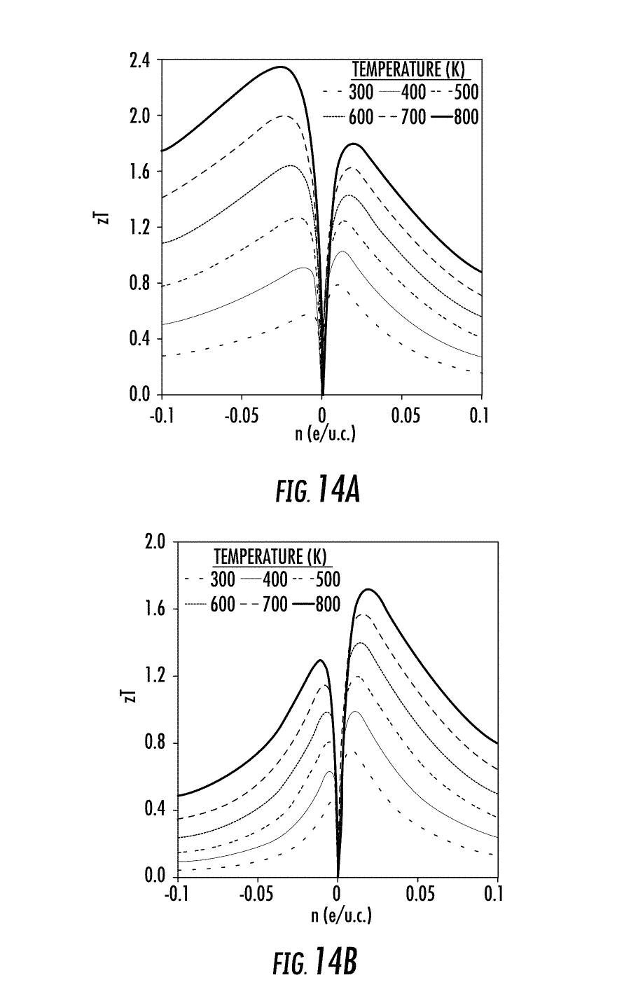

Based on this comparison between calculated cubic lattice parameter and powder XRD data, along with the difference in energy between coloring patterns, it can be assumed that Zn occupies the 4c site, despite prior LiZnPn structures having always preferred the pnictide on the 4c site. This site preference is not trivial, as it impacts the lattice constant as well as the band structure as shown in FIGS. 10A and 10B. Along with a difference in band gap, the nature of the band gap and lowest energy conduction bands change with coloring. With Zn in the 4c site, cubic LiZnSb has an indirect band gap of 1.2 eV, whereas with Sb in this site the material has a direct band gap of 1.3 eV. These differences significantly alter transport properties (as discussed with reference to FIGS. 9A-9D, below). With the crystal structure and most favorable site preference for the new cubic LiZnSb phase determined, a comparison in total energy can be made to the hexagonal polytype. As shown in FIG. 8C, the cubic polytype is energetically preferred across all unit cell volumes. This result is surprising because it indicates that the thermodynamically stable phase is not being formed at high temperature (in the bulk). However, all of the calculations were performed on stoichiometric phases while, based on past experiment, bulk hexagonal LiZnSb is known to be an unintentionally p-type doped, and likely non-stoichiometric, semiconductor. These computational results provide an explanation for the extreme difficulty researchers have faced while trying to synthesize stoichiometric or n-type compositions of LiZnSb using high temperature synthesis.

The transport properties and thermoelectric efficiencies of cubic LiZnSb at 600 K with either Zn or Sb occupying the heterocubic 4c site are shown in FIGS. 9A-9D. In both cases, the large Seebeck coefficients (FIG. 9A) gives rise to impressive power factors of over 110×10¹⁴ μW/cmK²s. However, when Sb occupies the 4c site, the peak in power factor occurs at a doping level that is too high to be useful (even at 0.3 e-/u.c. the power factor is still below 80×10¹⁴ μW/cmK²s). In contrast, when Zn occupies this site, the power factor increases much more abruptly with doping. As a result, despite Sb coloring having a slightly higher power factor, the thermal conductivity becomes too large which yields a smaller zT. By treating the electronic thermal conductivity according to Wiedemann-Franz law, where the Lorentz number is determined by the Seebeck coefficient, zT can be calculated using Equation 2, below. The benefit of this approach is that every variable, with the exception of κ₁/τ, can be obtained directly from the band structure.

$$zT = \frac{\frac{{S}^{2} σ}{τ}}{\frac{LT σ}{τ} + \frac{τ}{}} T \qquad ( Equation 2 )$$

The large zT found for n-type cubic LiZnSb is on a similar scale to the hexagonal polytype. However, as has been demonstrated for the hexagonal case and other Sb-based Zintl phases, synthesis of these compounds generally yields the p-type analogues (likely due to vacancies, as discussed before). This makes the large zT for p-type cubic LiZnSb especially promising.

In order to calculate zT, a common value of 1×10¹⁴ W/Kms was assumed for κ₁/τ, which makes a comparison with prior calculations on the hexagonal polytype more straightforward. This assumption was found to be in good agreement with experimental measurements on p-type hexagonal LiZnSb. One added benefit of the solution phase preparation of cubic LiZnSb is the tendency for hot injection methods to give reduced grain size, which causes a reduction in lattice thermal conductivity. This lowering of the lattice thermal conductivity by nanostructuring makes the assumption of κ₁/τ=1×10¹⁴ W/Kms relatively conservative and not overly optimistic. Thus, combining solution phase synthesis and nanostructuring to reduce the thermal conductivity could keep the extremely high power factor and place cubic LiZnSb among the highest efficiency thermoelectric materials for both n- and p-type compositions. Furthermore, its constituent elements and low temperature synthesis makes LiZnSb promising from a cost and toxicity perspective.

In summary, the methods and observations disclosed herein address the difficultly with synthesizing n-type or even stoichiometric compositions of the suggested hexagonal LiZnSb for thermoelectric applications. Further, through the use of low temperature solution phase methods, the first instance of polytypism within the Nowotny-Juza phases has been demonstrated. This cubic polytype shows the first example of a group II element occupying the heterocubic site, which has important implications on the band structure and ultimately the transport properties of this phase. The extremely high power factor of cubic LiZnSb at 600 K results in a promising zT for both n- and p-type doping of over 1.6 and 1.4, respectively. This result uses a conservative estimate for the lattice thermal conductivity which can likely be reduced below the value used through nanostructuring.

As a person having ordinary skill in the art will appreciate from this disclosure, nanocrystalline LiZnP, LiCdP, and LiZnSb were prepared at low temperature using a solution phase approach. The general approach to synthesis includes the use of TOP as a phosphorus source, lithium hydride or an organolithium reagent as the lithium precursor, and a highly reactive zinc precursor to immediately generate zinc metal in solution. XRD investigation confirmed the formation of phase-pure LiZnP samples with high crystallinity and thermal stability. The phase-pure nature of LiZnP was further shown through SAED. The optical properties match those of their bulk counterparts. This synthetic approach has the potential to be tuned to synthesize other Nowotny-Juza phases, shown through the synthesis of LiCdP and LiZnSb. LiZnSb, in particular, has good thermoelectric properties and has been the first Nowotny-Juza phase demonstrated to possess polytypism.

All references, including publications, patent applications, and patents cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A method of making a ternary compound, the method comprising the steps of:
providing a solution containing a group V element;
mixing a compound containing a group I/XI element into the solution containing the group V element to create a mixture containing the group I/XI element and the group V element;
injecting a compound containing a group II/XII element into the mixture at an elevated temperature; and
reacting the group II/XII element, the group I/XI element, and the group V element of the mixture to form the ternary compound.

2. The method of claim 1, wherein the group I/XI element is lithium.

3. The method of claim 2, wherein the group II/XII element is zinc.

4. The method of claim 3, wherein the group V element is phosphorus.

5. The method of claim 3, wherein the group V element is antimony.

6. The method of claim 2, wherein the group II/XII element is cadmium.

7. The method of claim 6, wherein the group V element is phosphorus.

8. The method according to claim 1, wherein the injecting step occurs when the mixture is at a temperature from 21° C. to 200° C.

9. The method according to claim 1, wherein the injecting step occurs when the mixture is at a temperature of 200° C. or higher.

10. The method according to claim 1, wherein the reacting step further comprises the step of heating the mixture to a temperature from 240° C. to 300° C.

11. The method according to claim 1, wherein the reacting step further comprises the step of heating the mixture to a temperature of 300° C. or higher.

12. A ternary compound comprising lithium, zinc, and antimony, wherein the ternary compound has a cubic structure.

13. The ternary compound of claim 12, wherein the zinc and antimony have a zinc blende crystal structure with an interpenetrating fcc lattice of lithium.

14. The ternary compound according to claim 12, wherein the ternary compound has a zT of 1.4 or higher.

15. The ternary compound according to claim 12, wherein zinc occupies a 4c site of the cubic structure.

16. The ternary compound according to claim 12, wherein the ternary compound is an n-type semiconductor.

17. The ternary compound according to claim 12, wherein antimony occupies the 4c site of the cubic structure.

18. The ternary compound according to claim 12, wherein the ternary compound is a p-type semiconductor.
